(19) United States
(12) Patent Application Publication
(10) Pub. No.: US 2022/0115167 A1
(43) Pub. Date: Apr. 14, 2022

(54) SUPERCONDUCTING WIRE AND PERMANENT CURRENT SWITCH

(71) Applicant: Sumitomo Electric Industries, Ltd., Osaka-shi, Osaka (JP)

(72) Inventors: Takashi YAMAGUCHI, Osaka-shi, Osaka (JP); Kotaro OHKI, Osaka-shi, Osaka (JP); Tatsuoki NAGAISHI, Osaka-shi, Osaka (JP)

(73) Assignee: Sumitomo Electric Industries, Ltd., Osaka-shi, Osaka (JP)

(21) Appl. No.: 17/428,655

(22) PCT Filed: Dec. 4, 2019
(86) PCT No.: PCT/JP2019/047393

§ 371 Date: Aug. 5, 2021

(30) Foreign Application Priority Data
Feb. 8, 2019 (JP) 2019-021621

(51) Int. Cl. H01B 12/04; H01B 12/06; H01L 39/18

(52) U.S. Cl. CPC H01B 12/04; H01L 39/18; H01B 12/06

(57) ABSTRACT

According to an embodiment, a superconducting wire includes a substrate, an intermediate layer formed on the substrate, a superconducting layer formed on the intermediate layer, and a protective layer formed on the superconducting layer. The superconducting layer has a first portion, a second portion, and a third portion between the first portion and the second portion in the longitudinal direction of the superconducting wire. The protective layer on the third portion is at least partially removed.

### TECHNICAL FIELD

The present disclosure relates to a superconducting wire and a permanent current switch. The present application claims priority based on Japanese Patent Application No. 2019-021621 filed on Feb. 8, 2019. The disclosure in the Japanese patent application is entirely incorporated herein by reference.

### BACKGROUND ART

PTL 1 (Japanese Patent Laid-Open No. 2018-117042) discloses a permanent current switch. The permanent current switch described in PTL 1 has a superconducting wire, and a heater wire to heat the superconducting wire.

The superconducting wire has a base layer, an orientation layer formed on the base layer, an intermediate layer formed on the orientation layer, a superconducting layer formed on the intermediate layer, and a protective layer formed on the superconducting layer. When the heater wire heats the superconducting wire, the superconducting wire has the superconducting layer brought to a normal conducting state.

### CITATION LIST

### Patent Literature

PTL 1: Japanese Patent Laid-Open No. 2018-117042

### SUMMARY OF INVENTION

In an aspect of the present disclosure, a superconducting wire comprises a substrate, an intermediate layer formed on the substrate, a superconducting layer formed on the intermediate layer, and a protective layer formed on the superconducting layer. The superconducting layer has a first portion, a second portion, and a third portion between the first portion and the second portion in a longitudinal direction of the superconducting wire. The protective layer on the third portion is at least partially removed.

### BRIEF DESCRIPTION OF DRAWINGS

FIG. 1 is a perspective view of a superconducting wire according to a first embodiment.

FIG. 2 is a cross section taken along a line II-II indicated in FIG. 1.

FIG. 3 is a cross section taken along a line III-III indicated in FIG. 1.

FIG. 4 is a cross section taken along a line IV-IV indicated in FIG. 1.

FIG. 5 is a flow chart of a process of a method for manufacturing a superconducting wire according to the first embodiment.

FIG. 6 is a cross-sectional perspective view of a superconducting member in a superconducting member preparation step.

FIG. 7 is a cross-sectional perspective view of a superconducting member 20 in a cutting step.

FIG. 8 is a schematic diagram showing a configuration of a permanent current switch according to the first embodiment.

FIG. 9 is an exploded perspective view of a superconducting wire and a heater in the permanent current switch according to the first embodiment.

FIG. 10 is a perspective view of a superconducting wire according to a second embodiment.

FIG. 11 is a cross section taken along a line XI-XI indicated in FIG. 10.

FIG. 12 is a cross section taken along a line XII-XII indicated in FIG. 10.

FIG. 13 is a cross section taken along a line XIII-XIII indicated in FIG. 10.

FIG. 14 is a perspective view of a superconducting wire 50 according to the second embodiment in an exemplary variation.

FIG. 15 is a flow chart of a process of a method for manufacturing a superconducting wire according to the second embodiment.

FIG. 16 is a schematic diagram of a permanent current switch according to the second embodiment.

FIG. 17 is a perspective view of a superconducting wire according to a third embodiment.

### DETAILED DESCRIPTION

### Problem to be Solved by the Present Disclosure

According to PTL 1, the protective layer is formed on the superconducting layer. Even when the heater wire heats the superconducting layer with a current passing therethrough and thus brings the superconducting layer into a normal conducting state, the current passing through the superconducting layer is mainly bypassed to the protective layer, which has a small value in electrical resistance. Accordingly, the permanent current switch described in PTL 1 requires an increased heated length for high electrical resistivity. Increased heated length requires an increased amount of heating, which would result in refrigerant evaporating in an increased amount. Furthermore, increasing an amount of heating requires a refrigerator to be enhanced in performance. Further, an increased heated length would result in the permanent current switch per se being increased in size. Thus, without having an increased heated length, the permanent current switch described in PTL 1 cannot be high in electrical resistivity, which would invite an increased operating cost. The present disclosure has been made in view of the above-described problem of conventional art. More specifically, the present disclosure provides a superconducting wire that can be high in electrical resistivity while having a short heated length, and a permanent current switch using the superconducting wire.

### Advantageous Effect of the Present Disclosure

A superconducting wire according to one aspect of the present disclosure can be high in electrical resistivity through heating.

### Description of Embodiments of the Present Disclosure

Initially, embodiments of the present disclosure will be enumerated and described.

(1) According to an embodiment, a superconducting wire comprises a substrate, an intermediate layer formed on the substrate, a superconducting layer formed on the intermediate layer, and a protective layer formed on the superconducting layer. The superconducting layer has a first portion, a second portion, and a third portion between the first portion and the second portion in a longitudinal direction of the superconducting wire. The protective layer on the third portion is at least partially removed.

In the superconducting wire of item (1) above, the protective layer on the third portion is at least partially removed. When the protective layer on the third portion is entirely removed, the protective layer on the first portion and the protective layer on the second portion are separated from each other and accordingly, there is no current path bypassing the third portion, and when the third portion is heated and transitions to a normal conducting state, a current flows through the third portion that has a value in electrical resistance increased by the normal conduction. Further, when the protective layer on the third portion is partially removed, and the third portion is heated and thus transitions to a normal conducting state, the current will be bypassed to the protective layer on the third portion, however, the protective layer on the third portion has electrical resistance increased by the partial removal. Thus, the superconducting wire of item (1) above can be high in electrical resistivity while having a short heated length.

(2) In the superconducting wire according to item (1) above, the protective layer on the third portion may entirely be removed.

(3) In the superconducting wire of item (2) above, in a plan view, the superconducting layer may have a peripheral edge inner than that of the intermediate layer.

(4) In the superconducting wire of item (2) or (3) above, in a plan view, the protective layer may have a peripheral edge inner than that of the intermediate layer.

(5) In the superconducting wire according to item (3) or (4) above, the substrate may have a first layer and a second layer. The first layer may be composed of stainless steel and the second layer may be composed of copper.

When the superconducting wire is formed by a mechanical slit, at least one of the substrate and the protective layer is deformed by the mechanical slit, and the superconducting layer and the substrate may be electrically interconnected. When the third portion with a current passing therethrough transitions to a normal conducting state with the superconducting layer and the substrate electrically interconnected, the current would be bypassed from the third portion to the substrate, and as a result, the superconducting wire may not be able to be high in electrical resistivity. This is particularly a matter of concern when the substrate has a layer of relatively soft copper. In this regard, in the superconducting wire of items (3) to (5) above, in a plan view, the superconducting layer (or the protective layer) has a peripheral edge inner than that of the intermediate layer, and when a mechanical slit is applied and at least one of the substrate and the protective layer is deformed thereby, the superconducting layer and the substrate are not easily electrically interconnected. Thus, the superconducting wire of items (3) to (5) above can more reliably be high in electrical resistivity while having a short heated length.

(6) According to an embodiment, a permanent current switch comprises the superconducting wire according to any one of items (1) to (5) above, and a heater. The heater is disposed to face the third portion of the superconducting layer.

### Detailed Description of Embodiments of the Present Disclosure

Reference will now be made to the drawings to describe embodiments of the present disclosure more specifically. In the figures, identical or equivalent components are identically denoted and will not be described redundantly.

### First Embodiment

A configuration of a superconducting wire 10 according to a first embodiment will be described.

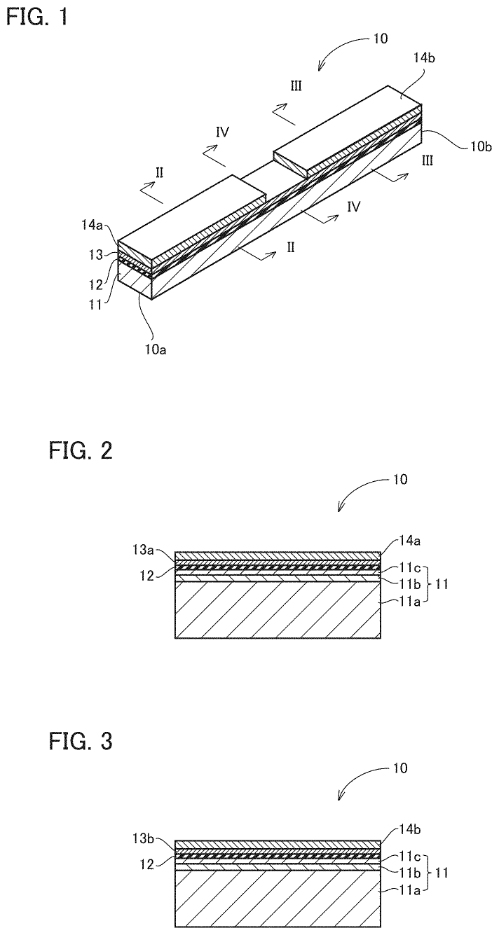

FIG. 1 is a perspective view of superconducting wire 10 according to the first embodiment. As shown in FIG. 1, superconducting wire 10 has a first end l0a and a second end 10b. First end l0a and second end 10b are ends of superconducting wire 10 in the longitudinal direction of superconducting wire 10. Second end 10b is an end opposite to first end 10a.

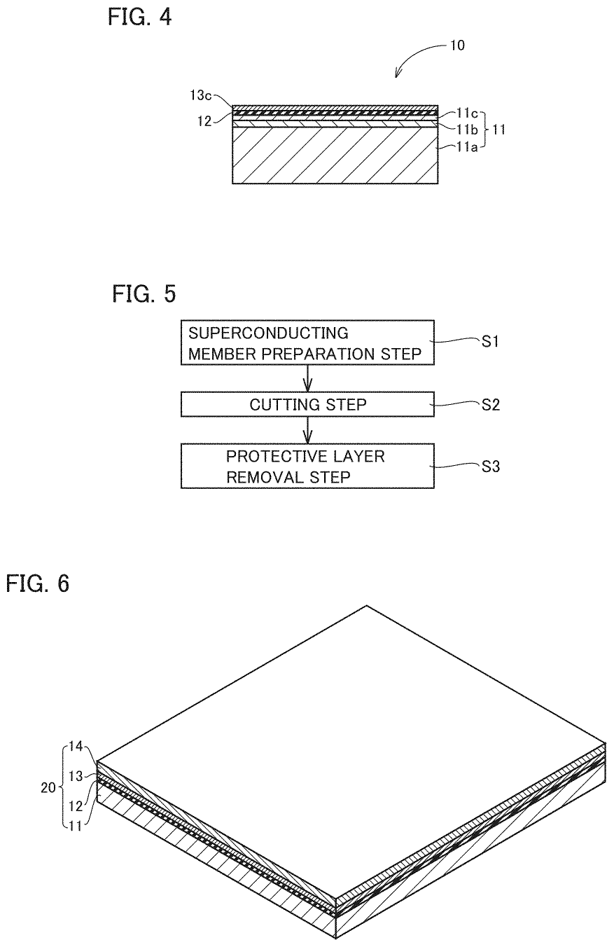

FIG. 2 is a cross section taken along a line II-II indicated in FIG. 1. FIG. 3 is a cross section taken along a line III-III indicated in FIG. 1. FIG. 4 is a cross section taken along a line IV-IV indicated in FIG. 1. As shown in FIGS. 2 to 4, superconducting wire 10 includes a substrate 11, an intermediate layer 12, a superconducting layer 13, and a protective layer 14a and a protective layer 14b.

Substrate 11 preferably has a first layer 11a, a second layer 11b, and a third layer 11c. Second layer 11b is formed on first layer 11a. Third layer 11c is formed on second layer 11b. First layer 11a is composed for example of stainless steel. First layer 11a may be composed for example of Hastelloy® or a similar nickel (Ni)-base alloy, nickel-tungsten (W) having texture introduced therein or a similar oriented nickel alloy, or the like. Second layer 11b is composed for example of copper (Cu). Note that second layer 11b being composed of a copper alloy is also included in “second layer 11b” being “composed of copper.” Third layer 11c is composed of nickel. Substrate 11 may not have second layer 11b and third layer 11c, and may be composed of first layer 11a alone.

Intermediate layer 12 is formed on substrate 11 (on third layer 11c). Intermediate layer 12 is composed of an insulating material. Intermediate layer 12 is composed for example of stabilized zirconium (YSZ), yttrium oxide (Y₂O₃), cerium oxide (CeO₂), or the like. Material for intermediate layer 12 is not limited to these materials.

Superconducting layer 13 is formed on intermediate layer 12. Superconducting layer 13 has a first portion 13a, a second portion 13b, and a third portion 13c in the longitudinal direction of superconducting wire 10. First portion 13a is located closer to first end 10a. Second portion 13b is located closer to second end 10b. Third portion 13c is located between first portion 13a and second portion 13b in the longitudinal direction of superconducting wire 10 (in other words, sandwiched by first portion 13a and second portion 13b).

Superconducting layer 13 is composed for example of an oxide superconductor. An example of this oxide superconductor is REBaCu₃Oy, where RE is a rare earth element. Examples of the rare earth element include yttrium (Y), praseodymium (Pr), neodymium (Nd), samarium (Sm), europium (Eu), gadolinium (Gd), holmium (Ho), ytterbium (Yb), and the like for example. REBaCu₃Oy may include two or more types of rare earth elements.

Protective layer 14a is formed on first portion 13a. Protective layer 14b is formed on second portion 13b. From another viewpoint, on third portion 13c, the protective layer is entirely removed (or no protective layer is formed), and protective layer 14a and protective layer 14b are separated from each other in the longitudinal direction of superconducting wire 10. Protective layer 14a and protective layer 14b are composed for example of silver (Ag). From another viewpoint, third portion 13c is exposed from a surface of superconducting wire 10. Although not shown, a stabilization layer may be formed on protective layer 14a and protective layer 14b. The stabilization layer is composed for example of copper, a copper alloy, or the like.

A method for manufacturing superconducting wire 10 according to the first embodiment will now be described. FIG. 5 is a flow chart of a process of a method for manufacturing superconducting wire 10 according to the first embodiment. As shown in FIG. 5, the method for manufacturing superconducting wire 10 includes a superconducting member preparation step S1, a cutting step S2, and a protective layer removal step S3.

In superconducting member preparation step S1, a superconducting member 20 is prepared. FIG. 6 is a cross-sectional perspective view of superconducting member 20 in superconducting member preparation step S1. As shown in FIG. 6, superconducting member 20 has substrate 11, intermediate layer 12, superconducting layer 13, and protective layer 14. Protective layer 14 is composed for example of silver.

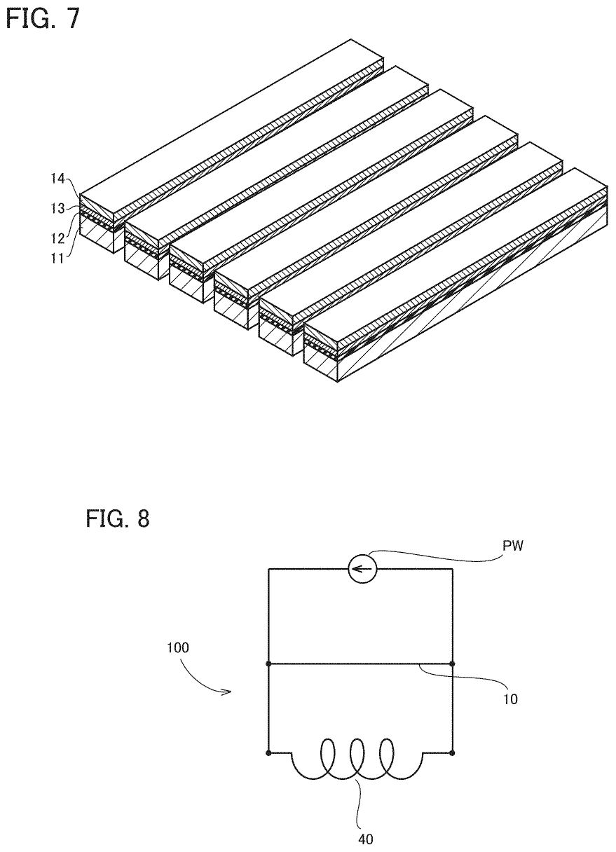

In cutting step S2, superconducting member 20 is cut. The cutting is preferably done by machining (with a mechanical slit). The cutting may be done by laser processing (with a laser slit). FIG. 7 is a cross-sectional perspective view of superconducting member 20 in cutting step S2. As shown in FIG. 7, in cutting step S2, a plurality of wires are cut out of superconducting member 20. This wire has the same structure as superconducting wire 10 except that protective layer 14 is formed on first portion 13a, second portion 13b, and third portion 13c.

In protective layer removal step S3, the wire cut out of superconducting member 20 has protective layer 14 partially removed therefrom. The wire cut out of superconducting member 20 has protective layer 14 partially etched away. This etching is performed by immersing the wire in etchant while protective layer 14 on first portion 13a and second portion 13b are masked and protective layer 14 on third portion 13c is unmasked. Thus, superconducting wire 10 having the structure shown in FIGS. 1 to 4 is manufactured. While the above indicates an example with protective layer removal step S3 performed after cutting step S2, cutting step S2 may be performed after protective layer removal step S3.

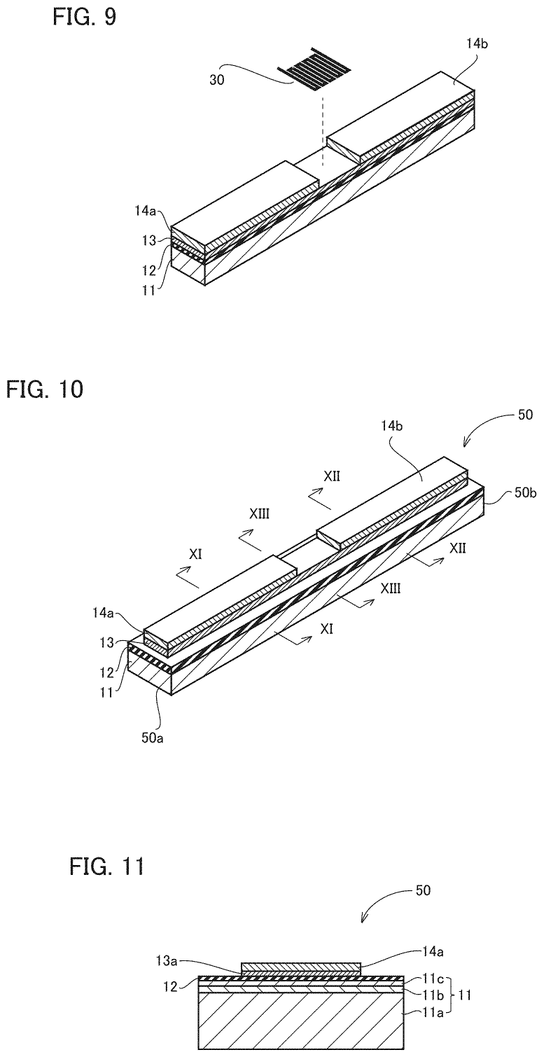

A configuration of a permanent current switch 100 according to the first embodiment will now be described. FIG. 8 is a schematic diagram showing a configuration of permanent current switch 100 according to the first embodiment. As shown in FIG. 8, permanent current switch 100 has superconducting wire 10 and a heater 30 (not shown in FIG. 8, see FIG. 9). Permanent current switch 100 causes a superconducting coil 40 to operate in a permanent current mode. Superconducting wire 10 and superconducting coil 40 are connected to power source PW in parallel. Superconducting wire 10 and superconducting coil 40 are cooled to a temperature equal to or lower than a superconducting transition temperature.

FIG. 9 is an exploded perspective view of superconducting wire 10 and heater 30 in permanent current switch 100 according to the first embodiment. As shown in FIG. 9, heater 30 is disposed so as to face third portion 13c. Heater 30 is composed for example of a nichrome wire.

When heater 30 is turned off (that is, when no current flows through heater 30), superconducting coil 40 has a coil impedance, and therefore, when a current is passed from a power source PW, the current exclusively flows in superconducting wire 10 through superconducting layer 13 having a superconducting state. Therefore, superconducting coil 40 is not excited (this state is referred to as a first state).

When heater 30 is turned on in the first state (that is, when a current is passed through heater 30), superconducting wire 10 has superconducting layer 13 (third portion 13c) brought to a normal conducting state. When passing a current is started in this state, the current also starts to flow through superconducting coil 40 (this state is referred to as a second state). Then, the current is gradually increased to an operating current, and when the operating current is reached and a predetermined period of time subsequently elapses, the current no longer flows through superconducting wire 10 and instead comes to flow exclusively through superconducting coil 40 (this state is referred to as a third state).

After the third state is reached, heater 30 is again turned off, and superconducting wire 10 has superconducting layer 13 (third portion 13c) brought back to a superconducting state. In that state, when the current from power source PW is gradually decreased, a portion of the current flowing through superconducting coil 40 comes to flow through superconducting wire 10 (this state is referred to as a fourth state).

After the fourth state is reached, the current from power source PW is further, gradually decreased to 0 ampere, and subsequently when a predetermined time elapses, the current comes to flow only through superconducting wire 10 and superconducting coil 40 (this state is referred to as a fifth state). Once the fifth state has been reached, the current continues to flow through superconducting wire 10 and superconducting coil 40 even when power source PW is disconnected (i.e., the permanent current mode). Permanent current switch 100 can thus cause superconducting coil 40 to operate in the permanent current mode.

Hereinafter, an effect of superconducting wire 10 of the first embodiment will be described. Protective layer 14a is formed on first portion 13a of superconducting layer 13, and protective layer 14b is formed on second portion 13b of superconducting layer 13. That is, no protective layer is formed on third portion 13c of superconducting layer 13 (in other words, the protective layer is removed therefrom), and protective layer 14a and protective layer 14b are separated from each other. Further, third portion 13c is formed on intermediate layer 12, and thus also insulated from substrate 11.

Accordingly, when third portion 13c is heated and thus transitions to a normal conducting state, a current will flow through third portion 13c as there is no current path bypassing third portion 13c. As third portion 13c is in the normal conducting state, it has an increased, large value in electrical resistance. Thus, superconducting wire 10 can be high in electrical resistivity while having a short heated length.

In superconducting wire 10, superconducting layer 13 (third portion 13c) is partially exposed from protective layer 14a and protective layer 14b, and third portion 13c can be efficiently heated.

### Second Embodiment

A configuration of a superconducting wire 50 according to a second embodiment will be described. Hereinafter, a point in configuration different from that of superconducting wire 10 according to the first embodiment will mainly be described, and redundant description will not be repeated.

Superconducting wire 50 has a first end 50a and a second end 50b opposite to first end 50a in the longitudinal direction of superconducting wire 50. Superconducting wire 50 includes a substrate 11, an intermediate layer 12 formed on substrate 11, a superconducting layer 13 formed on intermediate layer 12, and a protective layer 14a and a protective layer 14b. Substrate 11 has a first layer 11a, a second layer 11b formed on first layer 11a, and a third layer 11c formed on second layer 11b.

Superconducting layer 13 has a first portion 13a, a second portion 13b, and a third portion 13c located between first portion 13a and second portion 13b in the longitudinal direction of superconducting wire 50. Protective layer 14a is formed on first portion 13a, and protective layer 14b is formed on second portion 13b. That is, the protective layer is removed on third portion 13c. In these respects, superconducting wire 50 is the same in configuration as superconducting wire 10.

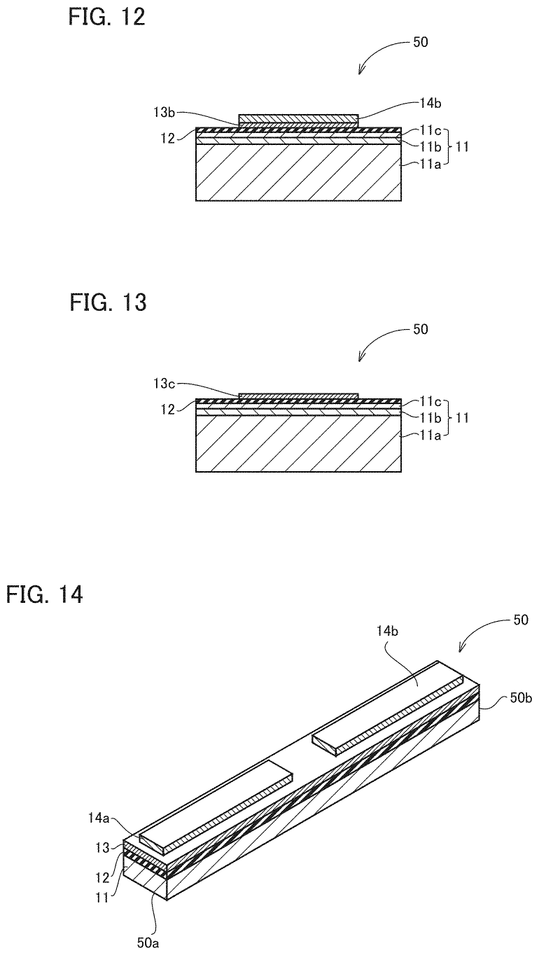

FIG. 10 is a perspective view of superconducting wire 50 according to the second embodiment. FIG. 11 is a cross section taken along a line XI-XI indicated in FIG. 10. FIG. 12 is a cross section taken along a line XII-XII indicated in FIG. 10. FIG. 13 is a cross section taken along a line XIII-XIII indicated in FIG. 10. As shown in FIGS. 10 to 13, in superconducting wire 50, in a plan view, superconducting layer 13 has a peripheral edge inner than that of intermediate layer 12. Further, in a plan view, protective layers 14a and 14b have their respective peripheral edges inner than that of intermediate layer 12. A “plan view” as referred to herein refers to a view in a direction orthogonal to a surface of superconducting wire 50.

More specifically, in a plan view in the longitudinal direction, superconducting layer 13, protective layer 14a, and protective layer 14b have their respective peripheral edges inner than that of intermediate layer 12, and in a plan view in a lateral direction (i.e., a direction intersecting the longitudinal direction), superconducting layer 13, protective layer 14a, and protective layer 14b have their respective peripheral edges inner than that of intermediate layer 12. In these respects, superconducting wire 50 is different in configuration from superconducting wire 10.

FIG. 14 is a perspective view of superconducting wire 50 according to the second embodiment in an exemplary variation. As shown in FIG. 14, in a plan view, only protective layer 14a and protective layer 14b may have their respective peripheral edges inner than that of intermediate layer 12, and superconducting layer 13 may not have a peripheral edge inner than that of intermediate layer 12.

A method for manufacturing superconducting wire 50 according to the second embodiment will now be described. Hereinafter, a point different from the method for manufacturing superconducting wire 10 according to the first embodiment will mainly be described, and redundant description will not be repeated.

The method for manufacturing superconducting wire 50 includes a superconducting member preparation step S1, a cutting step S2, and a protective layer removal step S3. In these respects, the method for manufacturing superconducting wire 50 is the same as that for manufacturing superconducting wire 10.

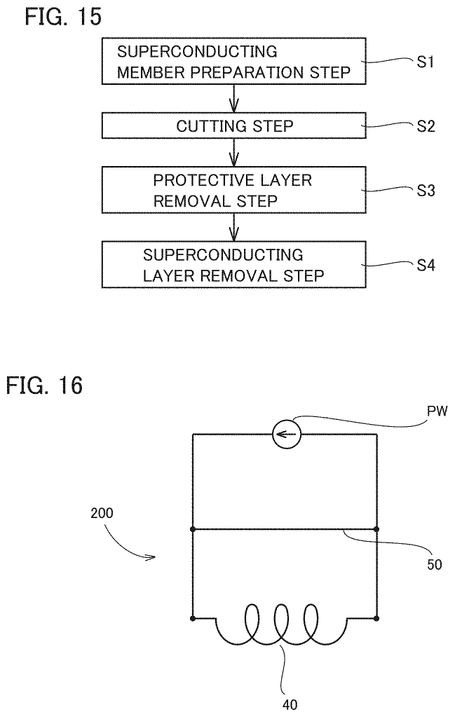

The method for manufacturing superconducting wire 50 is different from the method for manufacturing superconducting wire 10 in terms of details of protective layer removal step S3. FIG. 15 is a flow chart of a process of the method for manufacturing superconducting wire 50 according to the second embodiment. As shown in FIG. 15, the method for manufacturing superconducting wire 50 is also different from the method for manufacturing superconducting wire 10 in that the former further includes a superconducting layer removal step S4.

In the method for manufacturing superconducting wire 50, at protective layer removal step S3, protective layer 14 is masked in accordance with the shapes of protective layers 14a and 14b shown in FIG. 10. In this regard, protective layer removal step S3 in the method for manufacturing superconducting wire 50 is different from protective layer removal step S3 in the method for manufacturing superconducting wire 10.

In superconducting layer removal step S4, superconducting layer 13 is partially removed so that in a plan view, superconducting layer 13 has a peripheral edge inner than that of intermediate layer 12. Superconducting layer 13 is partially removed by etching, for example. Thus, superconducting wire 50 having the structure shown in FIGS. 10 to 14 is manufactured.

A configuration of a permanent current switch 200 according to the second embodiment will now be described. Hereinafter, a point in configuration different from that of permanent current switch 100 according to the first embodiment will mainly be described, and redundant description will not be repeated.

FIG. 16 is a schematic diagram of a permanent current switch according to the second embodiment. As shown in FIG. 16, the permanent current switch according to the second embodiment is similar in configuration to the permanent current switch according to the first embodiment except that superconducting wire 10 is replaced with superconducting wire 50.

Hereinafter, an effect of superconducting wire 50 of the second embodiment will be described. Note that hereinafter a point different from an effect of superconducting wire 10 according to the first embodiment will mainly be described, and redundant description will not be repeated.

When superconducting member 20 is cut with a mechanical slit, at least one of substrate 11 and the protective layer (protective layers 14a and 14b) is deformed thereby, and superconducting layer 13 and substrate 11 may be electrically interconnected. When third portion 13c transitions to a normal conducting state with superconducting layer 13 and substrate 11 electrically interconnected, third portion 13c may be bypassed and a current may flow to substrate 11. This is particularly a matter of concern when substrate 11 has a layer of relatively soft copper (i.e., second layer 11b).

In superconducting wire 50, in a plan view, superconducting layer 13 and the protective layer (protective layers 14a and 14b) have their peripheral edges inner than that of intermediate layer 12, and when a mechanical slit is applied and at least one of substrate 11 and the protective layer is deformed thereby, superconducting layer 13 and substrate 11 are not easily electrically interconnected. Thus, superconducting wire 50 can more reliably be high in electrical resistivity while having a short heated length.

### Third Embodiment

A configuration of a superconducting wire 60 according to a third embodiment will now be described. Hereinafter, a point in configuration different from that of superconducting wire 10 according to the first embodiment will mainly be described, and redundant description will not be repeated.

Superconducting wire 60 has a first end 60a and a second end 60b opposite to first end 60a in the longitudinal direction of superconducting wire 60. Superconducting wire 60 includes a substrate 11, an intermediate layer 12 formed on substrate 11, a superconducting layer 13 formed on intermediate layer 12, and a protective layer 14a and a protective layer 14b.

Superconducting layer 13 has a first portion 13a, a second portion 13b, and a third portion 13c located between first portion 13a and second portion 13b in the longitudinal direction of superconducting wire 60. Protective layer 14a is formed on first portion 13a, and protective layer 14b is formed on second portion 13b. In these respects, superconducting wire 60 is the same in configuration as superconducting wire 10.

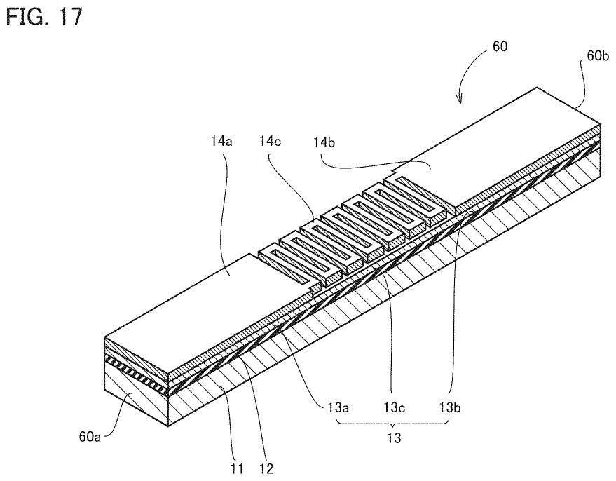

FIG. 17 is a perspective view of superconducting wire 60 according to the third embodiment. As shown in FIG. 17, in superconducting wire 60, the protective layer partially remains on third portion 13c. That is, superconducting wire 60 further includes a protective layer 14c formed on third portion 13c. Protective layer 14c is formed by partially removing a protective layer on third portion 13c. Protective layer 14c may electrically interconnect protective layer 14a and protective layer 14b. Protective layer 14c may have a meandering shape in a plan view. In these respects, superconducting wire 60 is different in configuration from superconducting wire 10.

A method for manufacturing superconducting wire 60 according to the third embodiment will be described. Hereinafter, a point different from the method for manufacturing superconducting wire 10 according to the first embodiment will mainly be described, and redundant description will not be repeated.

The method for manufacturing superconducting wire 60 is the same as the method for manufacturing superconducting wire 10 in that they both include a superconducting member preparation step S1, a cutting step S2, and a protective layer removal step S3. In the method for manufacturing superconducting wire 60, however, at protective layer removal step S3, protective layer 14 on third portion 13c is partially removed to form protective layer 14c. In this regard, the method for manufacturing superconducting wire 60 is different from the method for manufacturing superconducting wire 10.

Hereinafter, an effect of superconducting wire 60 of the third embodiment will be described. Note that hereinafter a point different from an effect of superconducting wire 10 according to the first embodiment will mainly be described, and redundant description will not be repeated.

When superconducting wire 60 has third portion 13c heated and thus brought to a normal conducting state, a current will be bypassed to protective layer 14c. Although the current is bypassed to protective layer 14c, protective layer 14c has a narrower current path than protective layer 14a and protective layer 14b do, and a value in electrical resistance for the bypassed current will be high. Thus, superconducting wire 60 can be high in electrical resistivity while having a short heated length.

It should be understood that the embodiments disclosed herein have been described for the purpose of illustration only and in a non-restrictive manner in any respect. The scope of the present invention is defined by the terms of the claims, rather than the embodiments described above, and is intended to include any modifications within the meaning and scope equivalent to the terms of the claims.

### REFERENCE SIGNS LIST

10 superconducting wire, 10a first end, 10b second end, 11 substrate, 11a first layer, 11b second layer, 11c third layer, 12 intermediate layer, 13 superconducting layer, 13a first portion, 13b second portion, 13c third portion, 14, 14a, 14b, 14c protective layer, 20 superconducting member, 30 heater, 40 superconducting coil, 50 superconducting wire, 50a first end, 50b second end, 60 superconducting wire, 60a first end, 60b second end, 100, 200 permanent current switch, PW power source, 51 superconducting member preparation step, S2 cutting step, S3 protective layer removal step, S4 superconducting layer removal step.

1. A superconducting wire comprising a substrate, an intermediate layer formed on the substrate, a superconducting layer formed on the intermediate layer, and a protective layer formed on the superconducting layer,
the superconducting layer having a first portion, a second portion, and a third portion between the first portion and the second portion in a longitudinal direction of the superconducting wire,
on the third portion the protective layer being at least partially removed.

2. The superconducting wire according to claim 1, wherein on the third portion the protective layer is entirely removed.

3. The superconducting wire according to claim 2, wherein in a plan view the superconducting layer has a peripheral edge inner than that of the intermediate layer.

4. The superconducting wire according to claim 2, wherein in a plan view the protective layer has a peripheral edge inner than that of the intermediate layer.

5. The superconducting wire according to claim 3, wherein
the substrate has a first layer and a second layer formed on the first layer,
the first layer is composed of stainless steel, a nickel-base alloy, or a nickel alloy, and
the second layer is composed of copper.

6. A permanent current switch comprising the superconducting wire according to claim 1, and a heater disposed so as to face the third portion.
